(19) United States
(12) Patent Application Publication
(10) Pub. No.: US 2011/0083055 A1
(43) Pub. Date: Apr. 7, 2011

(54) DECODING METHOD FOR RAPTOR CODES USING SYSTEM

(75) Inventors: Jun HEO, Seoul (KR); Kwangseok NOH, Uijeongbu-si (KR); Byung Gueon MIN, Seongnam (KR)

(73) Assignee: MEWTEL TECHNOLOGY INC., Seoul (KR)

(21) Appl. No.: 12/580,544

(22) Filed: Oct. 16, 2009

(30) Foreign Application Priority Data
Oct. 6, 2009 (KR) 10-2009-0094843

(51) Int. Cl. H03M 13/29; G06F 11/10

(52) U.S. Cl. 714/755; 714/E11.032

(57) ABSTRACT

The present invention relates to a decoding method for a raptor codes using system, which is capable of improving performance of the system and limiting increase in the amount of computation by grouping variable nodes if raptor codes are unsuccessfully decoded, to thereby increase a conjecture efficiency of variable node values. The decoding method is capable of improving performance of the system by making it possible to achieve performance improvement and additional reduction of the amount of computation even under an application of MP decoding by grouping variable nodes whose values cannot be known when decoded, dividing groups of variable nodes into sub groups, and conjecturing and recovering the variable nodes in a manner to exclude sub groups which do not satisfy check node equation.

### BACKGROUND OF THE INVENTION

1. Field of the Invention

The present invention relates to a decoding method for a raptor codes using system, and more particularly, to a decoding method for a raptor codes using system, which is capable of improving performance of the system and limiting increase in the amount of computation by grouping variable nodes if raptor codes are unsuccessfully decoded, to thereby increase a conjecture efficiency of variable node values.

2. Description of the Related Art

A fountain code with the amount of coded data undefined is used for multicasting in a computer network since the code allows complete receipt without any errors only with one-way information transmission even in the presence of difficulty in two-way information transmission, such as when a transmitter side has insufficient information on a receiver side or when there are too many receivers. Such a fountain code can reduce a request for re-transmission, which may impose overload on a network, and allows asynchronous receipt at the receivers. To this end, the transmitter transmits packets constantly decoded using a file to be transmitted, and each of the receivers receives and decodes only possibly decodable packets without a need of feedback.

A raptor code, as a kind of fountain code, was developed by Amin Shokrollahi at 2004 and was adopted as a standard for application layers of 3GPP MBMS, DVD-H and so on as it is advantageous over an existing Luby-Transform (LT) code, which is also a kind of fountain code, in terms of the amount of computation for decoding. The raptor code provides the better performance than the existing LT code in terms of the amount of computation for decoding. The biggest shortcoming of the LT code is nonlinearity of the amount of computation required for recovery of source symbols. On the contrary, for the purpose of overcoming the shortcoming of the LT code, the raptor code is more excellent in terms of convenience and efficiency in practical use since it can provide linearity of the amount of computation for decoding while maintaining linearity of the amount of computation for encoding.

A low density parity check code (LDPC) is one of the best channel codes which have been known up to now. The LDPC is that the contents, which had been proposed at 1962, were rediscovered and put to practical use at 1996, and provides excellent performance at a high code rate required for high speed data transmission. Accordingly, the LDPC is being adopted as a standard of services (e.g., WiBro, Long Term Evolution(LTE), etc.) for supporting high speed communication with recent advance of hardware. However, since a raptor code provides performance superior to the LDPC over a link layer using a binary erasure channel (BEC) and provides simple encoding, the raptor code is increasingly standardized in recent years.

The success of decoding of the raptor code depends on whether or not all pre-coding symbols can be recovered. A method of decoding the raptor code refers to a procedure of obtaining pre-coding symbols using on received symbols and a predefined code condition matrix A⁽⁰⁾ and recovering erased information symbols based on the obtained pre-coding symbols.

The procedure of obtaining the pre-coding symbols is accomplished by a Gaussian elimination method or a message passing (MP) method using the received symbols and the matrix A⁽⁰⁾.

In the meantime, a decoding method of LDPC code in BEC uses a scheme of applying a given parity check matrix H to the Gaussian elimination method or the MP method.

The MP method is characterized by very small amount of computation, although it has performance inferior to the Gaussian elimination method. Although the MP method uses a performance enhancement technique based on a conjecture in order to improve its low performance, it has a problem of exponential increase in the amount of computation. In addition, due to a difference in receiver structure between the LDPC and the raptor code, there is a problem of increase in the amount of computation when a conjecture technique used in the LDPC is employed in the raptor code, making it difficult to apply the currently proposed conjecture technique to the raptor code in a direct manner.

In general, if received symbols fail to be recovered, the received symbols are estimated based on a conjecture, and, if such estimation is unsuccessful, decoding results in failure. Up to now, the LDPC has the best performance of received symbol estimation based on the conjecture. Accordingly, the entire performance is improved as a rate of re-transmission due to the decoding failure is low. Such an estimation scheme for the LDPC has been improved in various ways, providing performance approximate to Nyquist limitation.

Hossein Pishro-Nik, FaramarzFekri, “On Decoding of Low-Density Parity-Check Codes over the BEC,” IEEE trans. Inf. Theory, vol. 50, No. 3, pp. 439-454, published on March, 2004 uses two conjecture technique. The first technique is to set values of conjecture nodes randomly, check whether or not values conjectured through MP decoding are correct, and if the conjectured values are not correct, reiterate this process, and the second technique is to search for conjecture nodes satisfying specified conditions, indicate a state of connection of conjecture nodes for all variable nodes, and apply a Gaussian elimination method.

However, in case of a system employing a raptor coding scheme, it is difficult to apply the Gaussian elimination method with the large amount of computation to the system, and further it is substantially difficult to apply an MP decoding-based conjecture scheme to the system in a direct manner because the amount of computation increases exponentially due to a difference in receiver structure between the raptor code and the LDPC.

Vellambi, B. N. and Fekri, F., “Its on the improved decoding algorithm for low-density parity-check codes over the binary erasure channel,” IEEE Trans. Inf. Theory, vol. 53, pp. 1510-1520, published at 2007, and Jiao, X.-P, Mu, J.-J, and Zhou, L.-H, “Modification of improved decoding algorithm for LDPC codes over BEC,” Electronics Letter, vol. 44, No. 8, pp. 542-543, published at 2008 disclose a scheme of indicating conjecture nodes for LDPC, configuring a bivalent check node based on a check node and the indicated conjecture nodes, and applying a Gaussian elimination method and a scheme of selecting conjecture nodes for the purpose of improving the former scheme. However, since these schemes are for LDPC as well, it is difficult to apply these schemes to the raptor code in a direct manner as well as to implement these schemes because of its large amount of computation.

In addition, Hillary Traus, John Bush, James Irvine and John Dunlop, “Exploiting Redundancies to Improve Performance of LT Decoding,” Communication network and services research conference (CNSR) discloses a performance improving technique used if an LT code, which is a fountain code similar to the raptor code, is unsuccessfully decoded. This technique improves performance by performing an MP decoding using information on variable nodes, which are not in common, if there are variable nodes connected in common to a plurality of check nodes. However, since this technique is extremely limited to conditions of the check nodes and the variable nodes, thereby providing insignificant improvement of performance, it is difficult to expect a noticeable effect even when this technique is applied to the raptor code.

Accordingly, there is a need of a new conjecture technique which is capable of recovering symbols with little limitation to a symbol recovery object in a system which uses a raptor code providing simple encoding and high performance over a link layer in a BEC environment, and capable of maintaining increase in the amount of computation at a linear level even when the number of conjecture nodes increases.

In particular, since a raptor code has a configuration where received symbols are separated from variable nodes, unlike an LDPC in which received symbols are directly connected to variable nodes, thereby immediately knowing variable node values upon receiving symbols, and if the raptor code has much more distributed variable nodes than the LDPC, the raptor code cannot use the existing conjecture technique for LDPC due to its sudden increase in the amount of computation, a new conjecture technique suitable for the raptor code is requisite for performance improvement.

### SUMMARY OF THE INVENTION

To overcome the above problems, it is therefore an object of the present invention to provide a decoding method for a raptor codes using system, which is capable of improving performance of the system by making it possible to achieve performance improvement and additional reduction of the amount of computation even under an application of MP decoding by grouping variable nodes whose values cannot be known when decoded, dividing groups of variable nodes into sub groups, and conjecturing and recovering the variable nodes in a manner to exclude sub groups which do not satisfy check node equation.

It is another object of the present invention to provide a decoding method for a raptor codes using system, which is capable of using an MP decoding scheme, which has the amount of computation even lower than a Gaussian elimination method although inferior in performance to the Gaussian elimination method, and linearly reducing the amount of computation which exponentially increases with increase of conjecture nodes while applying a conjecture scheme for improvement of performance of the MP decoding scheme.

It is still another object of the present invention to provide a decoding method for a raptor codes using system, which is capable of reducing the amount of computation according to a conjecture through grouping and sub grouping of variable node and balancing performance with the amount of computation by determining a limited value for check of a group order and the maximum limited number of groups.

To achieve the above object, according to an aspect of the invention, there is provided a decoding method for a raptor codes using system, comprising: a grouping step of decoding a raptor code in a message passing manner and grouping variable nodes, which are not recovered, into unit variable nodes corresponding to conjecture nodes; a sub grouping step of dividing each group into sub groups based on values of the conjecture nodes; and a sub group selecting step of regarding values of variable nodes of each group as a result of decoding by repeating a process of selecting a sub group satisfying a check node equation among the sub groups for all groups obtained in the grouping step.

Preferably, the grouping step further includes a step of performing a process of selecting conjecture nodes which can free corresponding variable nodes for the variable nodes which are not recovered and grouping the freed variable nodes in a non-overlapping manner until the all variable nodes are included in the group.

Preferably, if the number of groups exceeds a preset number, the decoding is regarded as unsuccessful.

Preferably, the sub group selecting step further includes a step of repeating a process of selecting a sub group satisfying the check node equation among sub groups of a corresponding group from the group having most variable nodes among groups of the grouping step up to an n-th group on the basis of group size, and thereafter, selecting a sub group satisfying the check node equation for the remaining groups irrespective of group size.

Preferably, the decoding method further comprises performing a process of repeating check of variable nodes freed by the conjecture node up to a preset D-th variable node in order to a group having the largest group size and selecting the next group among variable nodes except the group having the largest group size.

Preferably, a balance between performance and the amount of computation is adjusted by setting a limited value for the preset value D and the total number of groups.

Preferably, values of variable nodes according to sub groups selected for previous groups are used to check the check node equation for selection of sub groups of subsequent groups.

Preferably, the number n of groups determining an order according to the group size is 2, and the sub group selecting step is performed for the remaining groups irrespective of the order.

Preferably, the decoding method further comprises a step of regarding decoding as unsuccessful if none of check node equations to which sub groups for a particular group are connected are satisfied in the sub group selecting step.

Preferably, the decoding method further comprises a step of regarding decoding as unsuccessful if a union of variable nodes belonging to sub groups for all groups after completion of selection of the sub groups in the sub group selecting step is not equal to the number of initial variable nodes which were not recovered in the sub group selecting step.

According to another aspect of the invention, there is provided a decoding method for a raptor codes using system, comprising: a grouping step of repeating a process of grouping variable nodes freed by one conjecture node in an order of freeing variable nodes, which belong to a set U_{V} of variable nodes which are not recovered after decoding of a raptor code, with the one conjecture node, until all the variable nodes belonging to the U_{V} are grouped in a non-overlapping manner; a conjecture step of performing for all groups a process of checking whether or not a corresponding group does satisfy a check node equation when conjecture nodes corresponding to the corresponding group in an order of groups obtained in the grouping step are 0 and 1, determining a satisfying conjecture node, and using the determined conjecture node value when conjecture node values satisfying check node equations of subsequent groups are checked; and a variable node recovery step of performing the conjecture step for all groups and regarding values of variable nodes finally selected as a result of decoding.

Preferably, checking whether or not a corresponding group does satisfy a check node equation in the conjecture step includes checking all check nodes connected to the corresponding group and checking a conjecture node value satisfying at least one check node equation of the check nodes, and if there is no conjecture node value satisfying the check node equation for the all check nodes, decoding is regarded as unsuccessful.

Preferably, the grouping step further includes a step of performing a order check of selection groups according to number of the variable nodes up to an n-th variable node, and grouping the remaining variable nodes without checking of an order.

Preferably, n is 2.

Preferably, the grouping step further includes a step of regarding decoding as unsuccessful if the number of generated groups exceeds a preset limited number (gmax).

Preferably, a process of checking the number of variable nodes freed according to the conjecture node is limited to be repeated up to a preset D-the variable node.

Preferably, performance and the amount of computation are adjusted based on the preset limited number (gmax) and a preset variable node check limited number (D).

Preferably, the conjecture step further includes a step of checking check node equations of all check nodes to which corresponding groups are connected, with conjecture node values for the groups set to 0 and 1, and regarding decoding as unsuccessful if none of the check node equations are not satisfied.

### Effects of the Invention

According to an embodiment of the present invention, a decoding method for a raptor codes using system is capable of improving performance of the system by making it possible to achieve performance improvement and additional reduction of the amount of computation even under an application of MP decoding by grouping variable nodes whose values cannot be known when decoded, dividing groups of variable nodes into sub groups, and conjecturing and recovering the variable nodes in a manner to exclude sub groups which do not satisfy check node equation.

According to an embodiment of the present invention, a decoding method for a raptor codes using system is capable of using an MP decoding scheme, which has the amount of computation even lower than a Gaussian elimination method although inferior in performance to the Gaussian elimination method, and linearly reducing the amount of computation which exponentially increases with increase of conjecture nodes while applying a conjecture scheme for improvement of performance of the MP decoding scheme, which results in reduction of a system load.

According to an embodiment of the present invention, a decoding method for a raptor codes using system is capable of reducing the amount of computation according to a conjecture through grouping and sub grouping of variable node and balancing performance with the amount of computation by determining a limited value for check of a group order and the maximum limited number of groups, which results in performance optimization according to system and BEC (Binary Erasure Channel) environments.

### BRIEF DESCRIPTION OF THE DRAWINGS

The above and/or other aspects and advantages of the present invention will become apparent and more readily appreciated from the following description of the embodiments, taken in conjunction with the accompanying drawings of which:

FIG. 1 is a bipartite graph of a raptor code;

FIG. 2 is a bipartite graph of an LDPC code;

FIG. 3 is a graph showing MP decoding performance of a raptor code and an LDPC code;

FIG. 4 is a flow chart according to an embodiment of the present invention;

FIGS. 5 and 6 are detailed flow charts according to an embodiment of the present invention;

FIG. 7 is a bipartite graph of an example of raptor code MP decoding failure;

FIG. 8 shows an example of application of a conventional conjecture scheme;

FIG. 9 shows an example of application of a conjecture scheme according to an embodiment of the present invention;

FIG. 10 is a graph showing a difference in performance between embodiments of the present invention and a conventional scheme; and

FIG. 11 is a graph showing increase in the amount of computation between embodiments of the present invention.

### DETAILED DESCRIPTION OF THE PREFERRED EMBODIMENT

Hereinafter, the present invention will be described in detail by way of embodiments in conjunction with the accompanying drawings.

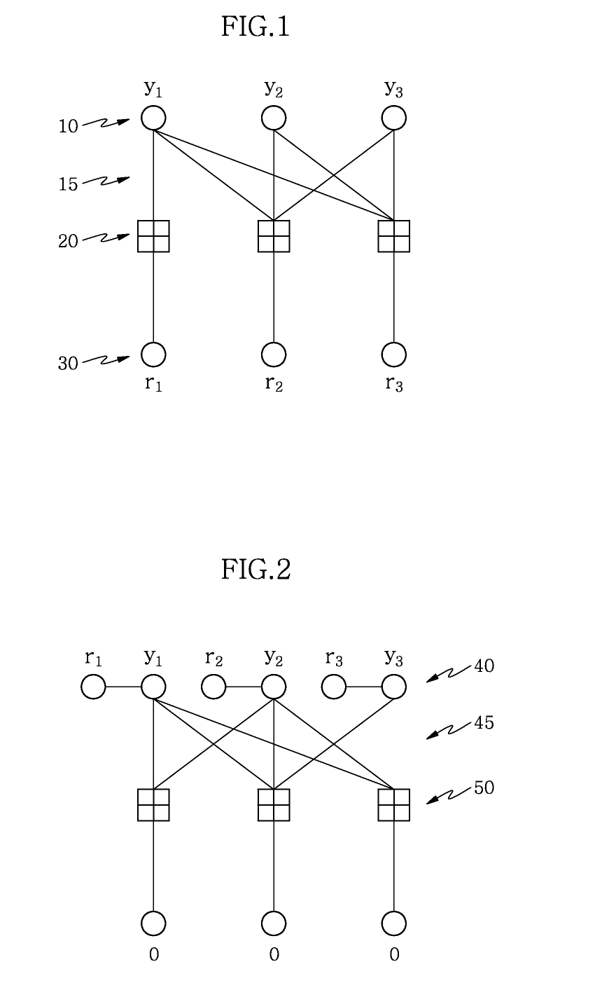

FIGS. 1 and 2 show a difference in receiver structure between a raptor code and an LDPC code. FIG. 1 is an example bipartite graph of a raptor code, showing received symbols (r₁, r₂ and r₃) 30, a relationship between variable nodes (y₁, y₂ and y₃) 30, which is estimated through a decoding procedure using these symbols, check nodes 20, and a connection state 15.

FIG. 2 is a bipartite graph of an LDPC code, showing received symbols (r₁, r₂ and r₃) 40, variable nodes (y₁, y₂ and y₃) 40, and check nodes 50, and a connection state 45.

As shown in these figures, for the LDPC code, values of the variable nodes can be immediately known upon receiving the symbols since the received symbols are directly connected to the variable nodes, but the raptor code has only to have performance inferior to the LDPC code since the received symbols 30 are connected to the check nodes 20 and the variable nodes 10 have to be obtained using the check nodes 20.

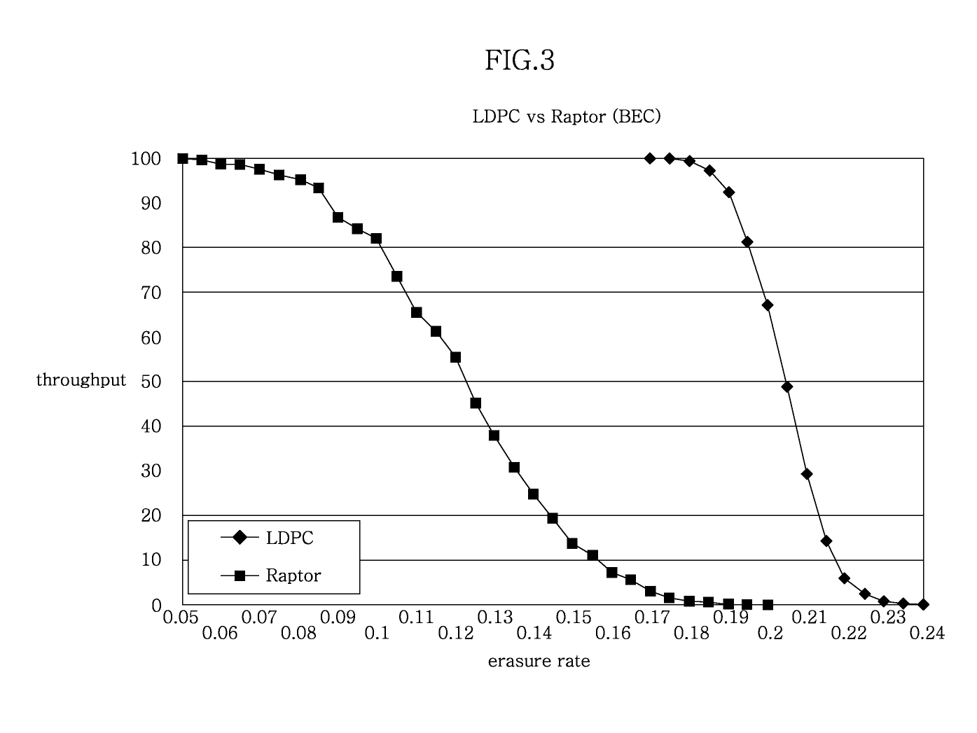

FIG. 3 shows performance of the raptor code and the LDPC code under conditions of approximately equal input size and code rate. It can be seen from the figure that the LDPC code with input size of 1512 and code rate of ¾ is superior in performance to the raptor code with input size of 1536 and code rate of ¾.

Under the above situation, assuming the LDPC code has the same BER (Bit Error Rate) as the raptor code, when a ratio of variable nodes unsuccessful in decoding to all variable nodes is measured, about 22 to 24% of all the variable nodes are unsuccessful, i.e., cannot be known for the LDPC code, while about 92 to 95% of all the variable nodes cannot be known for the raptor code.

This forces the raptor code to be further improved in its performance. A conjecture technique may be effective in such performance improvement. The conjecture technique is a method of correctly fining values of corresponding variable nodes by conjecturing some variable nodes whose values cannot be known when unsuccessful in decoding and repeating the decoding process or by using a Gaussian elimination method, an MP method or the like. In this case, as the number of variable nodes to be conjectured increases or the number of variable nodes used in the Gaussian elimination method or the MP method increases, the amount of computation exponentially increases.

However, since most of current conjecture techniques, which have been developed for use with LDPC, have too many variable nodes whose value cannot be known when unsuccessful in decoding, and accordingly have too many variable node required to be conjectured, as described above, if such conjecture techniques are applied to the raptor code, the amount of computation increases unacceptably.

As a result, when received symbols are not directly connected to variable nodes but connected to check nodes, as in the raptor code, a new conjecture technique is needed which is capable of reducing the amount of computation.

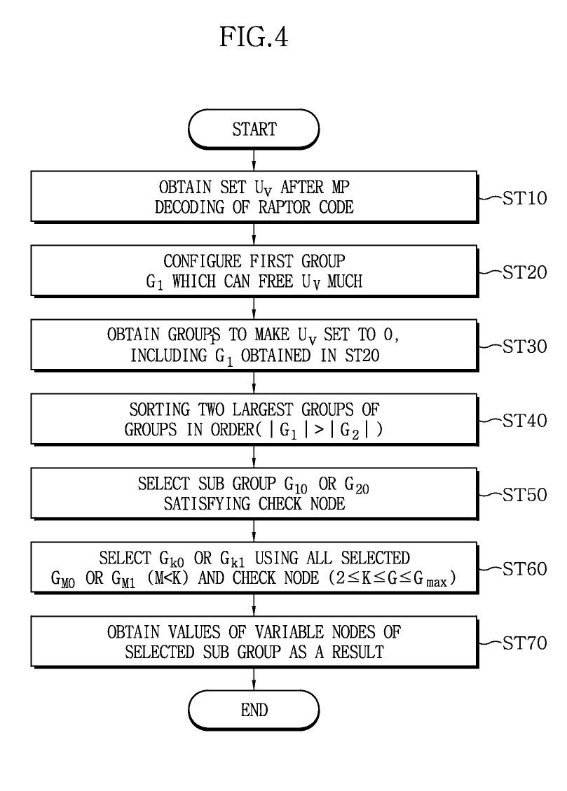

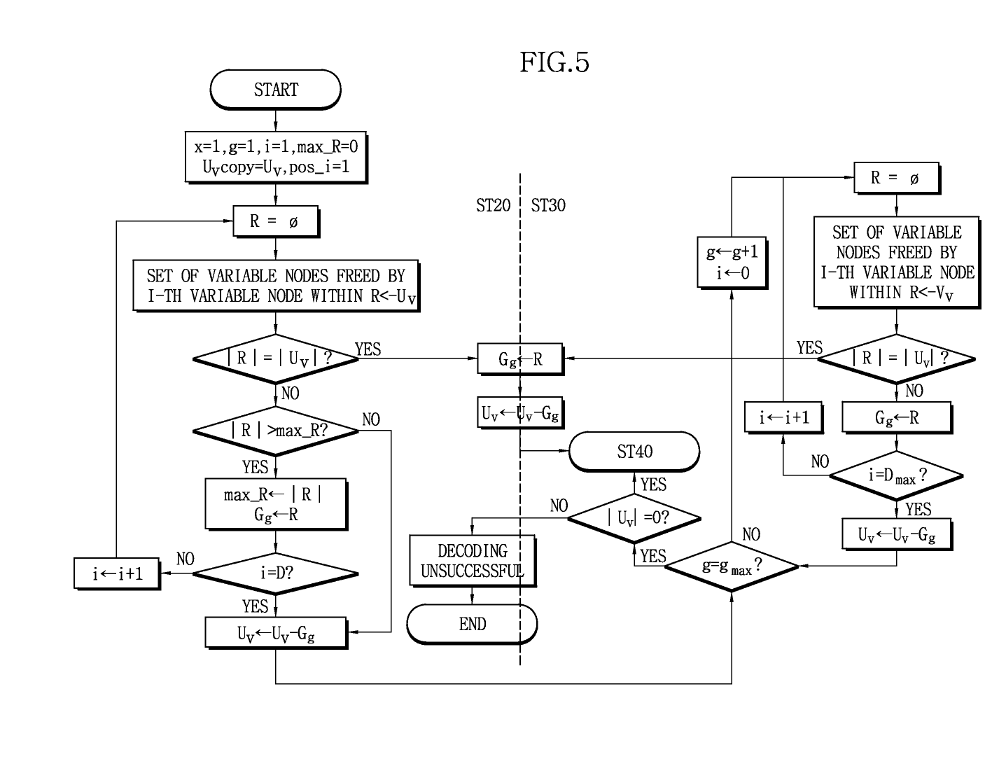

FIG. 4 is a flow chart showing a decoding method of a raptor code according to an embodiment of the present invention. Specifically, FIG. 4 shows a method of performing a decoding operation using a raptor code and applying a conjecture technique to variable nodes whose values cannot be known, thereby recovering the corresponding variable nodes.

First, variable nodes remaining after MP decoding of a raptor code are set as a set U_{V} (ST 10).

Next, conjecture nodes to make as many variable nodes as possible free are selected through a process of making variable node included in U_{V} know using one conjecture node, that is, confirming for each variable node whether or not individual nodes can be freed, and the selected conjecture nodes and the variable nodes freed by the conjecture nodes are configured as a first group (ST20).

In this manner, if a number of variable nodes which can be freed using one conjecture node is grouped as one group, when a weight is given to conjecture node which can free a number of variable nodes at once through repetition of such grouping and the weighted conjecture nodes are determined, it is possible to significantly reduce the amount of computation while improving performance.

Now, groups remaining except the variable node belonging to the group obtained in ST20 are obtained for U_{V}, with the number of groups set to the predetermined maximum number of gmax (ST30). If the number of obtained groups exceeds the predetermined gmax, decoding of the raptor code is regarded as unsuccessful. By setting such a maximum value to prevent excessive computation, it is possible to adjust a balance between performance and the amount of computation.

Now, values of the conjecture nodes should be estimated using the obtained groups, and in this case, since such estimation should be made from one having the highest priority, it is preferable to estimate values of the conjecture nodes in an order of group size. However, in order to determine the order according to the size of all groups, since whether or not each variable node is freed by a corresponding conjecture node should be checked for the variable nodes which can be freed at once in the group setting as mentioned previously, taking a long time about computation, it is preferable on experience and from a standpoint of performance vs. amount of computation that variable nodes are grouped irrespective of the order after several groups having high priority, and a subsequent sub group selection process also processes only several groups having high priority in an order but processes the remaining groups randomly.

In this embodiment, an order is decided for only two groups in an ascending order of group size but no order is decided for the remaining groups, thereby reducing the amount of computation while minimizing deterioration of performance. On the other hand, as will be described in detail with reference to FIG. 5, if the process of checking whether or not the individual variable nodes are freed in order to confirm the size of groups in the previous ST20 and ST30 is performed for all variable nodes belonging to U_{V}, since the amount of computation increases and a delay becomes long, it is preferable to reduce the amount of computation by checking whether or not only variable nodes up to the preset order (D) are freed.

Now, a process of dividing a corresponding group into sub groups based on values (1 or 0 under BEC environment) of conjecture nodes for the obtained groups is performed, and in this embodiment, two largest groups of the groups obtained in ST20 and ST30 are set as G₁ and G₂ in order and the remaining groups are made irrespective of the order (ST40).

After a sub group G₁₀ is set when a value of a conjecture node for group G₁ is set as ‘0’ and a sub group G₁₁ is set when the value is set as ‘1’, the sub group G₁₀ or G₁₁ satisfying a check node equation is selected (ST50). Of course, on the contrary, a method of excluding sub groups which do not satisfy the check node equation may be used. This process can be performed for all check nodes, and if there is no sub group which satisfies the check node equation for all the check nodes, decoding may be regarded as unsuccessful.

In this manner, when sub groups of groups which can free the most variable node are selected, this is to obtain values of the corresponding variable nodes. Accordingly, since the obtained values of the variable nodes can be utilized in a subsequent conjecture process, performance of symbol recovery based on the conjecture can be improved.

Now, a group G₂₀ or G₂₁ for the next-sized group which satisfies the check node equation is selected using the sub groups G₁₀ and G₁₁ selected in ST50. In this manner, a sub group Gₖ₀ or G_{K1} satisfying the check node equation is selected using the previously selected group and its sub groups (ST60).

Although an order is applied to only two groups in a size order in this embodiment, it should be noted that the order can be applied to more groups or a single group in consideration of the amount of computation and performance.

Thereafter, after repeating ST60 up to the g(≦gmax)-th group, when all sub groups for each group are selected, since a variable node value of the corresponding group becomes a result of decoding of the raptor code to allow variable nodes to be recovered, it is possible to recover received symbols with no re-transmission with the amount of computation as less as possible, which results in significant improvement of performance.

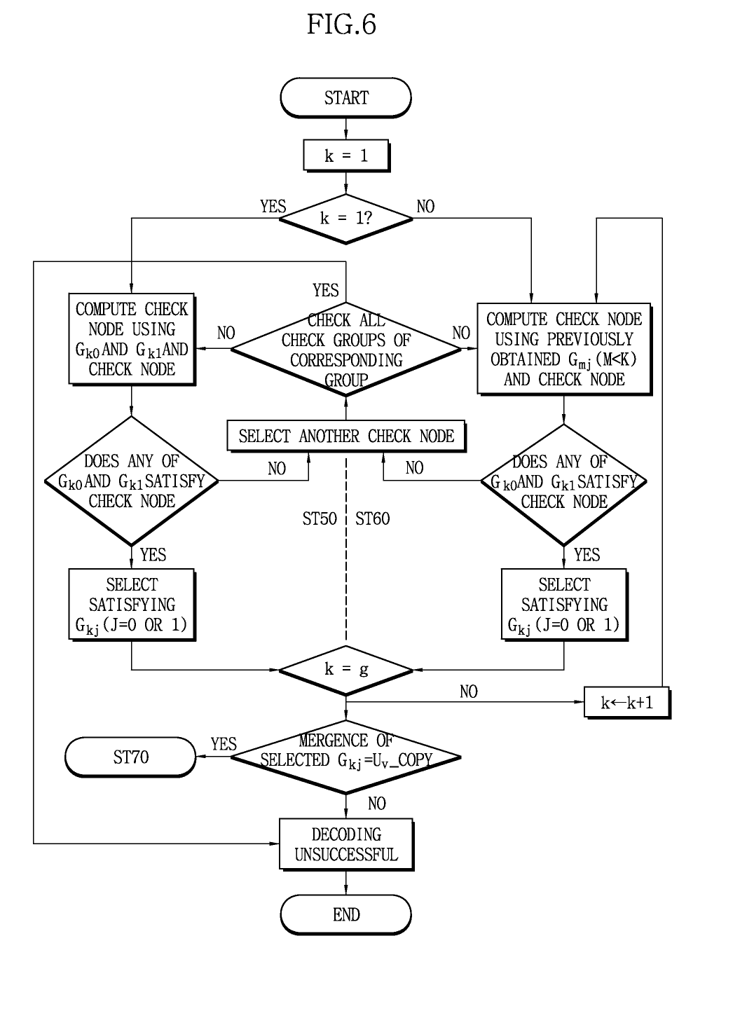

Now, the above-described method will be described in more detail with reference to FIGS. 5 and 6.

FIG. 5 is a flow chart showing details of the grouping process (ST20 and ST30) in FIG. 4, which can be implemented through actual programming. The left side in FIG. 5 shows the process corresponding to ST20 in FIG. 4, while the right side shows the process corresponding to ST30 in FIG. 4, and the method proceeds to ST40 after completion of these processes. It should be noted that the shown variables are assigned for substantial programming by way of example.

First, after initializing each variable, a group for a set UV of variable nodes remaining after MP decoding of a raptor code is selected. In this case, a first variable node of the variable nodes belonging to U_{V} is set as a conjecture node, and then the conjecture node and variable nodes to be freed are set as a set R.

If the size of the set R is equal to the size of U_{V}, it means that the corresponding conjecture node frees all U_{V}s and constructs a group G₁.

On the other hand, if the size of the set R is not equal to the size of U_{V}, the number of variable nodes freed by the conjecture node is repeatedly checked up to a preset D-th variable node. Among various sets R, the largest set R is set as G₁.

In this manner, by checking the freed variable nodes up to the D-th variable node, it is possible to reduce the amount of computation and a delay time and hence partially determine a balance between the total amount of computation and performance based on such a setting of D value.

Thereafter, the process in the right side in the flow chart is repeated up to the maximum gmax for U_{V} except R, completing a grouping process of dividing all U_{V}s into groups. If the grouping process is not completed when this process is repeated up to gmax, the decoding process of the raptor code is regarded as unsuccessful.

ST40 is the step of setting two largest groups of the groups obtained through the shown flow chart to be G₁ and G₂, respectively, and when only two groups are selected, a decoding operation can be speeded up.

FIG. 6 is a flow chart showing more details of the process of selecting sub groups, which corresponds to ST50 and ST60 in FIG. 4. As shown in detail in this figure, when conjecture node values for a group configured as shown are set as 0 and 1, the group is divided into sub groups, and a process of fining a sub group satisfying a check node equation among the resultant sub groups is performed with an application of example variables for programming. The left side in the flow chart of FIG. 6 corresponds to the step of ST50, while the right side corresponds to the step of ST60 which utilizes values of the obtained previous sub groups.

First, a value of a conjecture node in a group G₁ is set as ‘0’ and values of the remaining nodes in the group G₁ are obtained and represented by G₁₀. If the value of the conjecture node is set as ‘1’, the obtained values are represented by G₁₁.

Then, the check node equation for G₁₀ and G₁₁ is checked, and if any sub group which does not satisfy the check node equation is founded, a sub group satisfying the check node equation is selected and the checking on the check node equation for G₁₀ and G₁₁ is stopped. Accordingly, since the checking may be stopped in-between without requiring to check the check node equation throughout, the amount of computation can be further reduced as compared to the existing methods. If any sub group which does not satisfy the check node equation does not appear although the check node equation connected to G₁₀ and G₁₁ is throughout checked, decoding of the raptor code is regarded as unsuccessful.

As a sub group can be selected and values of variable nodes for the select sub group can be obtained and checked in the above process, the obtained values of variable nodes can be utilized in a subsequent process. This process is accomplished through the right side of the flow chart.

Then, the check node equation for the sub group (G₁₀ or G₁₁) and G₂₀ and G₂₁ obtained in the above process is checked. Like the previous process, if a sub group satisfying the check node equation is founded, the checking on the check node equation for G₂₀ and G₂₁ is stopped and the sub group satisfying the check node equation is selected. If the check node equation is not throughout satisfied, the decoding is regarded as unsuccessful.

Thereafter, the check node equation for the sub groups obtained previously in the same method as the selection of the second sub group and the sub groups Gₖ₀ and Gₖ₁ of the corresponding group is checked, and sub groups satisfying the check node equation are selected. (Of course, a method of excluding sub groups which do not satisfy the check node equation is also possible.) This process is repeated up to the total number g of groups.

After completion of selection of sub groups, if the union of variable nodes belonging to the selected sub groups is not equal to U_{V}, the decoding of the raptor code is regarded as unsuccessful; if the union is equal to U_{V}, values of the variable nodes of the selected sub groups becomes a result of decoding of the raptor code.

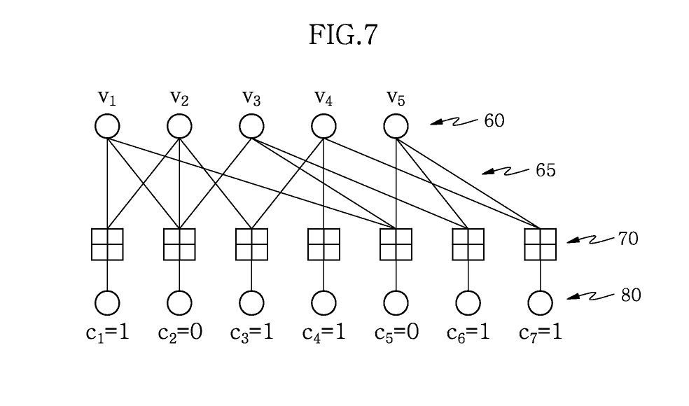

Now, an example of application of the embodiment according to the present invention will be described with reference to FIGS. 7 to 9.

FIG. 7 is a bipartite graph showing an example of raptor code MP decoding failure, where a set {v1,v2,v3,v4, v5} of variable nodes (v1 to v5) 60 is U_{V}. Although received symbols are connected to check nodes related to the set, since there is no variable node connected 65 to the check nodes 70 and having the number of “1”, decoding of the raptor code is impossible.

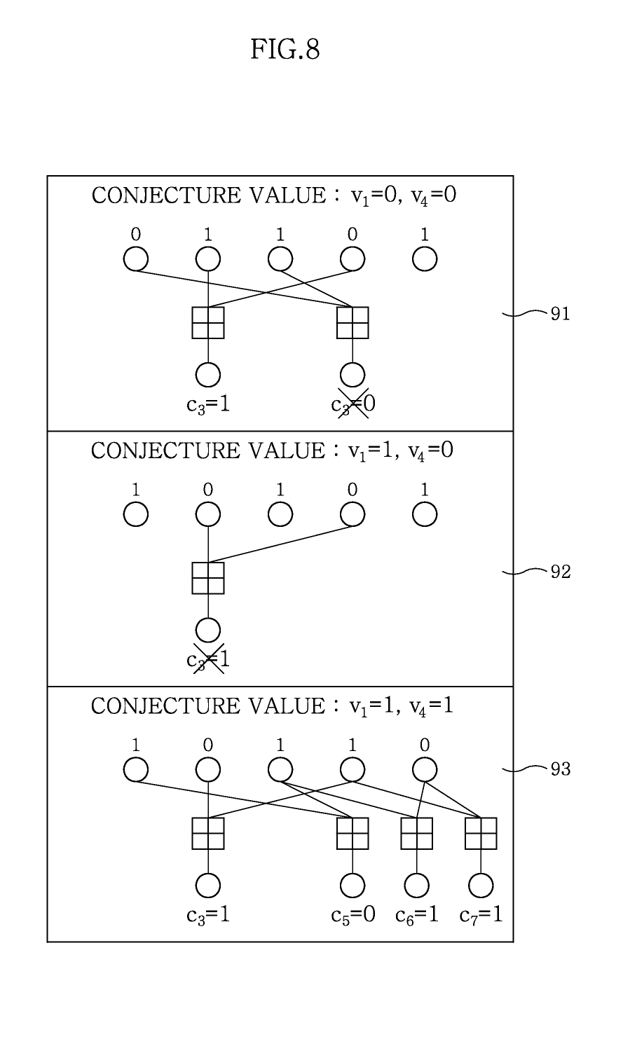

FIG. 8 shows an example of application of a conventional conjecture scheme to MP decoding, where v1 and v4 in U_{V} are first set as conjecture nodes and their values are set as ‘0’ as denoted by reference numeral 91. Values of the remaining v2, v3 and v5 can be known based on the v1 and v4 set as ‘0’ and check node equations c1, c2 and c3, but it is checked whether or not the remaining v2, v3 and v5 satisfy unused check node equations in order to confirm accuracy of conjecture values. It can be seen from this checking that c3 is satisfied but c5 is not satisfied, and v1(=0) and v4(=0) may be regarded as wrong conjecture.

Then, since variable nodes should be conjectured with values other than v1(=0) and v4(=0), v1 is set as 1 and v4 is set as 0 this time as denoted by reference numeral 92.

After obtaining values of the remaining variable nodes in U_{V}, the check node equations are checked as in the above manner 91. It can be seen from this checking that c3 is not satisfied and v1(=1) and v4(=0) are regarded as wrong conjecture.

Next, after v1 is set as 1 and v4 is set as 1, the check node equations are checked as denoted by reference numeral 93. Since c3, c5, c6 and c7 are all satisfied, conjecture values of v1(=1) and v4(=1) are correct, and thus v2(=1), v3(=1) and v5(=0) obtained based on these conjecture values can be represented as a decoding result of the raptor code.

However, this method is substantially difficult to be applied to a system employing the raptor code since the amount of computation exponentially increases when the number of conjecture nodes increases or the number of check nodes to be checked increases.

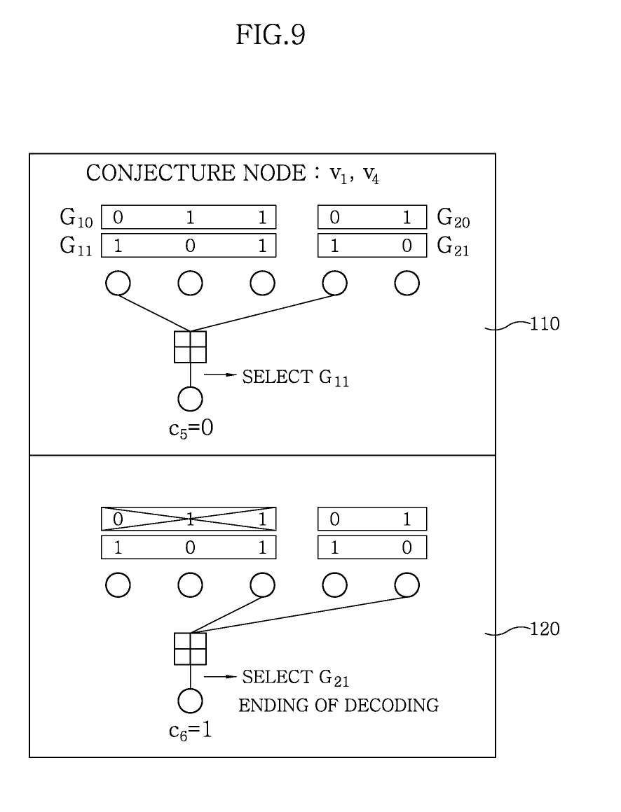

FIG. 9 shows an example of a conjecture scheme of recovering the variable nodes shown in FIG. 7 according to an embodiment of the present invention.

First, U_{V} is grouped into two groups using conjecture nodes v1 and v4, and each group is divided into subgroups whose conjecture nodes have values of ‘0’ or ‘1’. Values of variable nodes within each sub group except conjecture nodes can be obtained using check node equations.

First, after all U_{V}s are divided into sub groups, check node equations for G₁₀ and G₁₁ are first checked 110. Since a group which does not satisfy c5 is G₁₀, G₁₁ is selected.

Next, a check node c6 for the previously obtained G11 and sub groups G₂₀ and G₂₁ of the second group is checked 120. Since G₂₀ is not satisfied in c6, G₂₁ is selected. Accordingly, a result of conjecture according to the present invention becomes values of variable nodes in the selected sub groups, which is the same result as FIG. 8.

As a result, the present invention provides even simpler computation without deteriorating performance since the amount of computation does not exponentially increase even if the number of conjecture nodes increases.

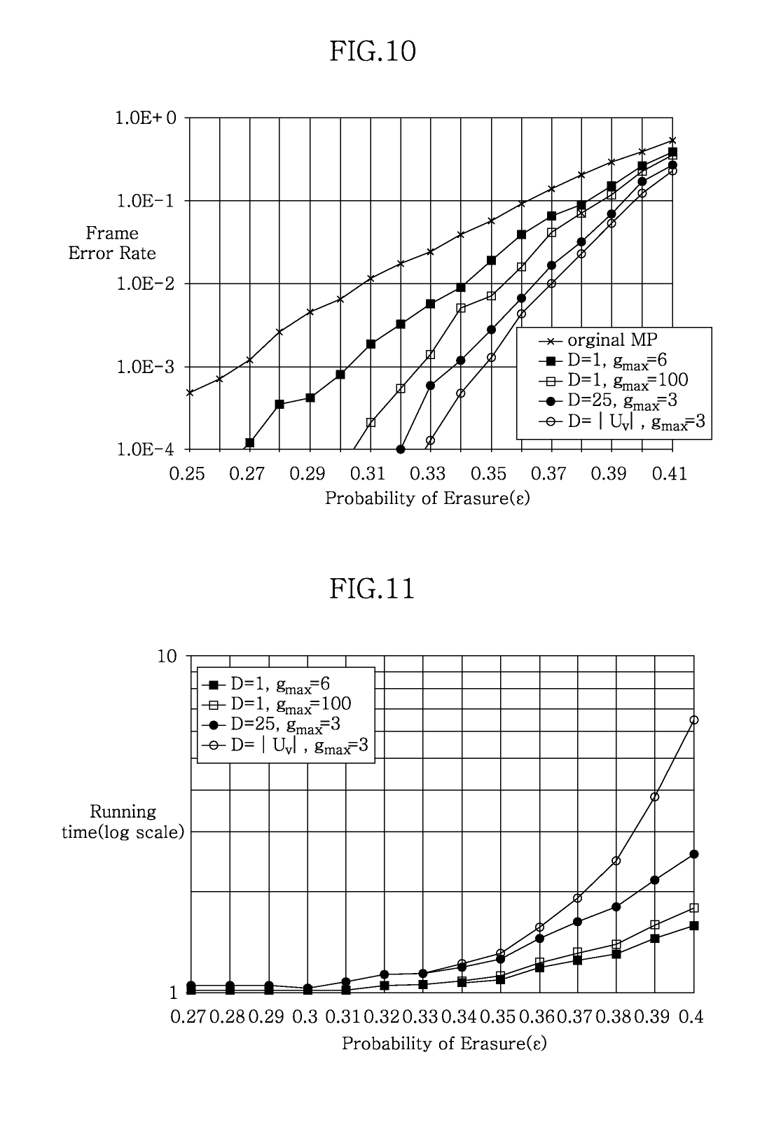

FIG. 10 is a graph showing a performance comparison between decoding according to an embodiment of the present invention and conventional MP decoding. It can be seen from the graph that improvement of performance depends on D and gmax and the highest improvement of performance can be achieved when D=|U_{V}| and gmax=3. On the other hand, it is seen that performance is lowest when D=1 and gmax=6, but shows noticeable improvement over conventional MP decoding schemes. In other words, when an erasure rate is 0.27, it can be seen that even an example application of the embodiment of the present invention, which has the lowest performance, is ten times or so lower in frame error rate than conventional schemes.

FIG. 11 is a graph showing the amount of computation depending on D and gmax when the amount of computation for MP decoding is 1. It can be seen from this graph that, as an erasure rate of a BEC channel increases, the amount of computation rapidly increases when D=|U_{V}| and gmax=3, and the amount of computation minimally increases when D=1 and gamx=6. That is, the performance graph of FIG. 11 shows a result opposed to the performance graph of FIG. 10 and it can be accordingly seen that the amount of computation increases as improvement of performance increases.

Accordingly, the performance and the amount of computation can be adjusted depending on D and gmax, and in any case, the decoding method of the present invention provides performance superior to the conventional MP decoding scheme, thereby allowing a pertinent design depending on system and BEC conditions and so on.

While the present invention has been particularly shown and described with reference to exemplary embodiments thereof, it will be understood by those skilled in the art that various changes in form and details may be made therein without departing from the spirit and scope of the present invention. The exemplary embodiments are provided for the purpose of illustrating the invention, not in a limitative sense. Thus, it is intended that the present invention covers the modifications and variations of this invention provided they come within the scope of the appended claims and their equivalents.

What is claimed is:

1. A decoding method for a raptor codes using system, comprising:
a grouping step of decoding a raptor code in a message passing manner and grouping variable nodes, which are not recovered, into unit variable nodes corresponding to conjecture nodes;
a sub grouping step of dividing each group into sub groups based on values of the conjecture nodes; and
a sub group selecting step of regarding values of variable nodes of each group as a result of decoding by repeating a process of selecting a sub group satisfying a check node equation among the sub groups for all groups obtained in the grouping step.

2. The decoding method according to claim 1, wherein the grouping step further includes a step of performing a process of selecting conjecture nodes which can free corresponding variable nodes for the variable nodes which are not recovered and grouping the freed variable nodes in a non-overlapping manner until the all variable nodes are included in the group.

3. The decoding method according to claim 2, wherein, if the number of groups exceeds a preset number, the decoding is regarded as unsuccessful.

4. The decoding method according to claim 1, wherein the sub group selecting step further includes a step of repeating a process of selecting a sub group satisfying the check node equation among sub groups of a corresponding group from the group having most variable nodes among groups of the grouping step up to an n-th group on the basis of group size, and thereafter, selecting a sub group satisfying the check node equation for the remaining groups irrespective of group size.

5. The decoding method according to claim 4, further comprising performing a process of repeating check of variable nodes freed by the conjecture node up to a preset D-th variable node in order to a group having the largest group size and selecting the next group among variable nodes except the group having the largest group size.

6. The decoding method according to claim 5, wherein a balance between performance and the amount of computation is adjusted by setting a limited value for the preset value D and the total number of groups.

7. The decoding method according to claim 4, wherein values of variable nodes according to sub groups selected for previous groups are used to check the check node equation for selection of sub groups of subsequent groups.

8. The decoding method according to claim 4, wherein the number n of groups determining an order according to the group size is 2, and the sub group selecting step is performed for the remaining groups irrespective of the order.

9. The decoding method according to claim 1, further comprising a step of regarding decoding as unsuccessful if none of check node equations to which sub groups for a particular group are connected are satisfied in the sub group selecting step.

10. The decoding method according to claim 1, further comprising a step of regarding decoding as unsuccessful if a union of variable nodes belonging to sub groups for all groups after completion of selection of the sub groups in the sub group selecting step is not equal to the number of initial variable nodes which were not recovered in the sub group selecting step.

11. A decoding method for a raptor codes using system, comprising:
a grouping step of repeating a process of grouping variable nodes freed by one conjecture node in an order of freeing variable nodes, which belong to a set U_{V} of variable nodes which are not recovered after decoding of a raptor code, with the one conjecture node, until all the variable nodes belonging to the U_{V} are grouped in a non-overlapping manner;
a conjecture step of performing for all groups a process of checking whether or not a corresponding group does satisfy a check node equation when conjecture nodes corresponding to the corresponding group in an order of groups obtained in the grouping step are 0 and 1, determining a satisfying conjecture node, and using the determined conjecture node value when conjecture node values satisfying check node equations of subsequent groups are checked; and
a variable node recovery step of performing the conjecture step for all groups and regarding values of variable nodes finally selected as a result of decoding.

12. The decoding method according to claim 11, wherein checking whether or not a corresponding group does satisfy a check node equation in the conjecture step includes checking all check nodes connected to the corresponding group and checking a conjecture node value satisfying at least one check node equation of the check nodes, and if there is no conjecture node value satisfying the check node equation for the all check nodes, decoding is regarded as unsuccessful.

13. The decoding method according to claim 12, wherein the grouping step further includes a step of performing a order check of selection groups according to number of the variable nodes up to an n-th variable node, and grouping the remaining variable nodes without checking of an order.

14. The decoding method according to claim 13, wherein n is 2.

15. The decoding method according to claim 11, wherein the grouping step further includes a step of regarding decoding as unsuccessful if the number of generated groups exceeds a preset limited number (gmax).

16. The decoding method according to claim 15, wherein a process of checking the number of variable nodes freed according to the conjecture node is limited to be repeated up to a preset D-the variable node.

17. The decoding method according to claim 16, wherein performance and the amount of computation are adjusted based on the preset limited number (gmax) and a preset variable node check limited number (D).

18. The decoding method according to claim 11, wherein the conjecture step further includes a step of checking check node equations of all check nodes to which corresponding groups are connected, with conjecture node values for the groups set to 0 and 1, and regarding decoding as unsuccessful if none of the check node equations are not satisfied.
